(19) United States
(12) Patent Application Publication
(10) Pub. No.: US 2007/0178670 A1
(43) Pub. Date: Aug. 2, 2007

(54) METHODS FOR PREPARING CRYSTALLINE FILMS

(75) Inventors: Suvankar Sengupta, Hilliard, OH (US); Ramachandra Rao Revur, Columbus, OH (US); Troy A. Pyles, Hilliard, OH (US)

Correspondence Address: CALFEE HALTER & GRISWOLD, LLP, 800 SUPERIOR AVENUE, SUITE 1400, CLEVELAND, OH, 44114, US

(73) Assignee: METAMATERIA PARTNERS LLC, Columbus, OH (US)

(21) Appl. No.: 11/625,271

(22) Filed: Jan. 19, 2007

Related U.S. Application Data
(60) Provisional application No. 60/760,772, filed on Jan. 19, 2006.

(51) Int. Cl. H01L 21/20

(52) U.S. Cl. 438/478

(57) ABSTRACT

Methods of forming crystalline films on a substrate are provided. The crystalline films may be formed using amorphous nanoparticles. Methods of forming dispersions of amorphous nanoparticles are also provided.

### CROSS-REFERENCE TO RELATED APPLICATION

This application is based on U.S. Provisional Application Ser. No. 60/760,772, filed Jan. 19, 2006, the benefit of which is hereby claimed and the disclosure of which is hereby incorporated herein by reference.

### STATEMENT REGARDING FEDERALLY FUNDED RESEARCH

This application was made with Government support under SBIR No. FA9950-05-C-0076. The Government has certain rights in this invention.

### BACKGROUND

Many different techniques for fabricating epitaxial films are described in patents and in the scientific literature. These methods include vapor phase deposition techniques like RF sputtering, DC sputtering, molecular beam epitaxy (MBE), magnetron sputtering, thermal evaporation, electron beam evaporation, pulsed laser deposition (PLD), and metal organic chemical vapor deposition (MOCVD) or liquid phase processes like spin coating and dip coating of solutions like metal organic deposition (MOD).

For example, superconducting YBa₂Cu₃Oₓ and doped YBa₂Cu₃Oₓ films may be prepared by using an MOD process. In this technique, metals forming the epitaxial film are dissolved in trifluoroacetic acid to form a solution of metal trifluoroacetate salts dissolved in the trifluoroacetic acid and the coating solution so formed is applied to a substrate. The composite so formed is then heated to elevated temperature, which causes the solvent to evaporate, the trifluoroacetate salts to discompose in situ and the metals forming these salts to grow epitaxially from the substrate. This technique is commonly known as the “TFA-MOD” method, which refers to trifluoroacetic acid metal organic decomposition. See, Izumi et al., “Progress in R&D for Coated Conductors by TFA-MOD Processing,” IEEE Transactions on Applied Superconductivity, Vol. 15, No. 2, June 2005; Fuji et al., “Progress on TFA-MOD coated conductor development,” Physica C 426-431 (2005) 938-944, available on-line at www.sciencedirect.com; and Teranishi et al., “High-I_{c} processing for YBCO coated conductors by TFA-MOD process,” Physica C 426-431 (2005) 959-965, available on-line at www.sciencedirect.com. The disclosures of these documents are also incorporated herein by reference.

Other analogous MOD processes for making crystalline coatings, i.e., other coating processes in which an organic solution of metal organic salts is deposited on a substrate and then heated to decompose the organic salts and cause nucleation and growth of the desired coating, may also be used. See, in general, Bhyiyan, “TOPICAL REVIEW, Solution-derived textured oxide thin films-a review,” Superconductivity Science Technology, Vol. 19, Institute of Physics Publishing, Jan. 4, 2006, the disclosure of which is also incorporated herein by reference.

In prior art MOD processes for forming crystalline coatings, one starts with a solution. The substrate is then coated (spin coating, dip coating, flow coating, spray coating etc). The film is heat treated. The film, gels, pyrolyzes, etc and then nucleates and grows. If the substrate is a single crystal, and there is not much difference in the lattice structure, the film will grow epitaxially with the substrate.

Epitaxial films may be deposited by using vapor phase (Physical and Chemical) or liquid phase (Liquid phase epitaxy, Metalorganic decomposition, etc) deposition. In these techniques, the film nucleates at the substrates and may grow epitaxially. Depending on the deposition technique, the substrate temperature, and film growth rates determines whether the film grows epitaxially or form a randomly oriented polycrystalline structure.

Sol-gel technique is another approach that has been used to produce films from the solutions. In this approach, a gel film is formed by hydrolysis or other reaction. A gel (network in a continuous liquid phase) coating is formed which is then heat treated to drive off the water and other liquids. As water or other solvent is removed the network becomes smaller forming xerogel. The xerogel is heat treated to form a crystalline coating.

According to various methods in the prior art for forming crystalline and eptiaxial crystalline films, the conditions and materials can adversely influence the end product. For example, pyrolysis of organic source compounds normally occurs in prior art processes such as MOD and TFA-MOD, and the associated decomposition products can adversely affects density and integrity of the formed film. In some instances, film thickness can be adversely affected, both as a result of the organic pyrolisis, and due to the limitations in density of the pre-crystallized coatings formed according to conventional techniques. These effects on coating properties in turn can adversely influence the rate of film heating and end product processing. Additional, according to various conventional processes, noxious substances such as HF are generated, such as in the TFA-MOD process. Accordingly, improved processes for forming crystalline films are desirable.

### SUMMARY

In accordance with various embodiments, processes are provided for making a crystalline film on a substrate by applying to the substrate amorphous nanoparticles and heating the coated substrate to cause the constituents of the amorphous nanoparticles to nucleate and grow on the substrate to form a crystalline film.

In accordance with other embodiments, processes are provided for forming a stable dispersion of amorphous nanoparticles comprising heating a mixture of a non-reactive solvent and organic salts of one or more metals to a temperature sufficient to cause the one or more organic metal salts to decompose into amorphous nanoparticles that are stably dispersed in the non-reactive solvent.

In accordance with yet other embodiments, processes are provided for forming a metal oxide epitaxial film on a substrate comprising heating a mixture of a non-reactive solvent and at least one organometallic salt to decompose the at least one organometallic salt into amorphous nanoparticles that are stably dispersed in the non-reactive solvent. Thereafter, the dispersion of amorphous nanoparticles is applied to the substrate that exhibits a crystallographic structure, and the coated substrate is heated to cause the metal constituents of the amorphous nanoparticles to nucleate and grow on the substrate to form an epitaxial crystalline film.

### BRIEF DESCRIPTION OF THE DRAWINGS

The following detailed description of embodiments of the present invention can be best understood when read in conjunction with the following drawings, in which:

FIG. 1 shows the thermogravimetric and differential thermal analysis of a sample of YBCO nanoparticles, prepared according to one embodiment the invention;

FIG. 2 is the X-ray diffraction pattern of a YBCO epitaxial film prepared from a colloidal dispersion of YBCO nanoparticles according to one embodiment of the invention;

FIG. 3 is a microphotograph showing the microstructure of a YBCO epitaxial film prepared from a colloidal dispersion of YBCO nanoparticles according one embodiment of the invention; and

FIG. 4 shows particle size distribution of Cerium oxide nanoparticles.

### DETAILED DESCRIPTION

The present invention will now be described with occasional reference to the specific embodiments of the invention. This invention may, however, be embodied in different forms and should not be construed as limited to the embodiments set forth herein. Rather, these embodiments are provided so that this disclosure will be thorough and complete.

Unless otherwise defined, all technical and scientific terms used herein have the same meaning as commonly understood by one of ordinary skill in the art to which this invention belongs. The terminology used in the description of the invention herein is for describing particular embodiments only and is not intended to be limiting of the invention. As used in the description of the invention and the appended claims, the singular forms “a,” “an,” and “the” are intended to include the plural forms as well, unless the context clearly indicates otherwise. All publications, patent applications, patents, and other references mentioned herein are incorporated by reference in their entirety.

Unless otherwise indicated, all numbers expressing quantities of ingredients, properties such as molecular weight, reaction conditions, and so forth as used in the specification and claims are to be understood as being modified in all instances by the term “about.” Accordingly, unless otherwise indicated, the numerical properties set forth in the following specification and claims are approximations that may vary depending on the desired properties sought to be obtained in embodiments of the present invention. Notwithstanding that the numerical ranges and parameters setting forth the broad scope of the invention are approximations, the numerical values set forth in the specific examples are reported as precisely as possible. Any numerical values, however, inherently contain certain errors necessarily resulting from error found in their respective measurements.

The present invention in some embodiments provides methods for making a crystalline film on a substrate comprising coating the substrate with amorphous nanoparticles and then heating these amorphous nanoparticles to cause the constituents forming these nanoparticles to nucleate and grow on the substrate to form a crystalline film on the substrate. In some embodiments, the amorphous nanoparticles may be in the form of dispersions of amorphous nanoparticles that are coated on the substrate. In some examples, the crystalline films may be grown epitaxially.

In other embodiments, the present invention provides processes for forming a stable dispersion of amorphous nanoparticles useful in producing crystalline films, the processes comprising combining organic salts of a metal or metals that form the films with a non-reactive solvent and heating the composition so formed to cause these organic salts to decompose into amorphous nanoparticles stably dispersed in the solvent.

In yet further embodiments, the present invention provides processes for forming a metal oxide crystalline film on a substrate comprising heating a mixture of a non-reactive solvent and organic salts of the metals that form the crystalline film to decompose these organic salts into amorphous nanoparticles stably dispersed in the non-reactive solvent, applying the dispersion so formed to the substrate, and heating to cause the metals forming the amorphous nanoparticles to grow on the substrate to form a metal oxide crystalline film on the substrate. In some examples, the amorphous nanoparticles may be grown epitaxially from the substrate.

For purposes of defining and describing the present invention, the term “amorphous nanoparticles” shall be understood as referring to nanoparticles that have no real or apparent crystalline form. It will be understood that, in some examples, amorphous nanoparticles may be obtained from starting materials that have a real or apparent crystalline form. For purposes of defining and describing the present invention, the term “metal” shall be understood as referring to those elements to the left of a line drawn between the elements boron (B) and polonium (Po) on the Periodic Table including Al, Ga, Ge, Sn, Sb and Bi. In addition, for purposes of defining and describing the present invention, the term “epitaxial film” shall be understood as referring to a film that grows with a crystallographic relationship with the substrate. For instance, a single crystal substrate will yield a single crystal epitaxial film.

Crystalline Films

In accordance with the embodiments discussed above, a variety of crystalline films may be formed. This invention can be used to form crystalline films of any chemical composition. For example, crystalline films may include, but are not limited to, metal oxide films, nonoxide metal films, ceramic metal semiconductor films, and intermetallic semiconductor films. For example, the nonoxide metal crystalline films may have a chemical composition of AlN or PbTe.

In some examples, this invention is used to make crystalline oxide films, i.e., films composed of a single metal oxide as well as films composed of a composite of multiple metal oxides arranged in a distinct crystallographic structure. Examples of films formed from single metal oxides include, but are not limited to, metal monoxides such as MgO, NiO, CoO and ZnO, especially those exhibiting the rock salt and wurtzite structures, metal dioxides such as CeO₂, ZrO₂, VO₂, TiO₂ and SnO₂, for example, those exhibiting the fluorite and rutile structures, and metal trioxides such as In₂O₃, Tb₂O₃, Y₂O₃, Gd₂O₃ and Eu₂O₃, for example, those exhibiting the bixbyite and corundum structures.

Additional examples of crystalline oxide films formed from composite metal oxides include, but are not limited to, those exhibiting the bixbyite structure such as HoGdO, YbGdO, CeGdO and InSnO, for example. Yet further examples include, but are not limited to, those metal oxide films exhibiting the perovskite structure (ABO₃) such as LaAlO₃, GdFeO₃, SrTiO₃, BaCeO₃, BaₓSr₁₋ₓTiO₃, BaZrO₃, BaSnO₃, BaZr_{0.35}Ti_{0.65}O₃, La₁₋ₓCaₓMnO₃, LaNiO₃, (Pb,Sr)TiO₃, [Pb(Sc_{0.5}Nb_{0.5})]ₓTi₁₋ₓO₃, Pb₁₋ₓCaₓTiO₃, PbTiO₃, Pb(Yb,Nb)TiO₃, PbZrO₃, Pb(Zr,Ti)O₃ and SrRuO₃. Additional examples include, but are not limited to, films formed from composite metal oxides exhibiting the pyrochlore structure (A₂B₂O₇) such as La₂Zr₂O₇, Gd₂Zr₂O₇,Eu₂Nb₂O₇, Gd₂Nb₂O₇, Sm₂Nb₂O₇, Ho₂Nb₂O₇, Y₃NbO₇ and Yb₃NbO₇. Still other oxides films which can be made by this invention include those formed from ZnO, WO₃, Ta₂O₅, MgTiO₃, MgAl₂O₃, LiAlO₂, (Ca,Sr)WO₄, Bi₄V₆O₂₁.

Yet further examples of oxide films include those described in the above-noted Bhyiyan article. It is also well-known that these oxide films can be doped with a wide variety of different doping elements including, but not limited to, Y, Hg, Tl and the lanthanide elements (La through Yb). See, the above-noted Bhyiyan article. All such dopants can be used in this invention.

In some embodiments, the methods of this invention may be applied to produce metal oxide films corresponding to the formula MₐQ_{b}Cu_{c}Oₓ, including YBaCuOₓ films (commonly referred to as “YBCO” film) which are often made by the above-noted TFA-MOD procedures. In general, such films can be regarded as complex perovskites corresponding to the formula MₐQ_{b}Cu_{c}Oₓ, wherein: M is one or more metals selected from Y, La, Ce, Pr, Nd, Pm, Sm, Eu, Gd, Tb, Dy, Ho, Fr, Tm, Yb, Lu and Bi; Q is one or more Group IIa elements selected from Ca, Sr, Mg and Ba; c=1-3, a+b≧c, a+b+c=3-8; and x is a number to sufficient to satisfy the valence requirements of the other elements present For example, complex oxides of this type include those in which M is Y, optionally doped with one or more other lanthanides. In other examples, complex oxides of this type include those which Q is Ba, Sr or both and in which b+c=2-3. In yet further examples, complex oxides of this type include those in which a+b+c=3-5. In other examples, complex oxides of this type include compounds of the formula YBa₂Cu₃O_{7-δ}. In some examples, complex oxides of this type include compounds in which some or all of the Y is replaced with one or more of the other M elements listed above.

In some particular examples, metal-copper oxide films of average composition M₂Ba₂CuOₓ, MBa₂Cu₃Oₓ, MBa₂Ca₂Cu₃Oₓ, or Bi₂Sr₂CaCu₂Oₓ may be prepared. These formulae represent the average compositions of bulk materials, therefore x may have non-integer values. For the same reason, it should be understood that the numerical subscripts in the formulae, as presented in the specification and claims, are not meant to be exact. Thus, compounds such as MBa_{1.9}Ca_{2.1}Cu₃Oₓ are intended to be represented by the formulae above, and are intended to be within the scope of the claims. In these formulae, M represents one or more metals selected from the group consisting of Hg, TI, and the lanthanide elements (La through Yb). The value of x ranges from about 4 to about 9, depending upon the identity and member of metal atoms, as is well-known in the art (see, e.g., H. Kamimura, Theory of Copper Oxide Superconductors, 2005, Springer-Verlag, Berlin).

In other examples, epitaxial films of oxides such as BaTiO₃, LaMnO₃, and CeO₂ may be made.

Amorphous Nanoparticles

Any suitable amorphous nanoparticles may be used in conjunction with the methods of the present invention. Generally, the amorphous nanoparticles are chosen to contain the metals that are desired in the final crystalline film. The nanoparticles may be of any suitable size. For example, the nanoparticles may have sizes ranging from less than about 1 nm to about 500 nm in diameter. In other examples, the size of the synthesized nanoparticles ranges from about 10 nm to about 100 nm. In yet other examples, the size of the synthesized nanoparticles ranges from about 28 nm to about 50 nm. In further examples, the average size of the synthesized nanoparticles may be about 5, 10, 15, 20, 25, 30, 35, 40, 50, 75, 100, 200 or 500 nm.

When the amorphous nanoparticles are coated on a substrate and a crystalline film is subsequently formed, the amorphous nanoparticles are chosen to comprise the metals that make up the crystalline film. In some examples, the nanoparticles contain the metals that make up the crystalline film in the desired stochiometry, i.e., in ratios corresponding to the crystalline coating to be formed. This stochiometry may be achieved in any suitable manner. For example, the desired stochiometry may be achieved by formulating the individual nanoparticles to have the desired stoichiometry.

As discussed above, in accordance with some embodiments of the present invention, the amorphous nanoparticles are coated on a substrate and subsequently heated. The amorphous nanoparticles that are to be coated on a substrate may be provided in any suitable form. For example, an essentially liquid-free batch of particulate free-flowing nanoparticles can be applied to and physically spread over the substrate to be coated by any suitable means, if desired.

In other examples, the amorphous nanoparticles are provided to be coated on the substrate in the form of a dispersion of the amorphous nanoparticles in a suitable liquid (the “dispersion liquid”). The dispersion liquid may comprise any suitable liquid. In some examples, the dispersion liquid is non-reactive, i.e., it exhibits little or no tendency to react with the other ingredients of the dispersion.

The dispersion of amorphous nanoparticles may be formed in any suitable manner. For example, nanoparticles may be formed in a reaction mixture and subsequently separated from the reaction mixture in which they are generated. For example, the amorphous nanoparticles may be separated from the reaction mixture by centrifugation or filtration. The amorphous nanoparticles may then subsequently be re-suspended in any desired dispersion liquid at any desired concentration.

Nanoparticles (which includes nanopowders) are known in the art, and may be prepared as colloidal suspensions (dispersions) by other known methods. For example, the amorphous nanoparticles may be synthesized by any methods known to one skilled in the art including, but not limited to, sonochemical synthesis, organometallic decomposition, microemulsion precipitation and sol-gel techniques.

In other examples, the amorphous nanoparticle dispersion may be formed in accordance with the inventive methods as further described herein. Namely, a stable dispersion of amorphous nanoparticles useful in producing crystalline films may be formed by combining organic salts of a metal or metals that form the films with a non-reactive solvent and heating the composition so formed to cause these organic salts to decompose into amorphous nanoparticles stably dispersed in the solvent.

In some embodiments, the amorphous nanoparticle dispersion is formed in situ, that is, in the liquid that will be the dispersion liquid. One way this can be done, for example, is by forming a solution of organic salts of the metals forming the desired coating, combining this solution with the dispersion liquid, and then treating the mixture so formed to cause these organic metal salts to decompose into amorphous nanoparticles stably dispersed in this dispersion liquid. It has been found that this can be done, i.e., stable dispersions of amorphous nanoparticles can be formed, by heating (for example, refluxing) such mixtures above the decomposition temperatures of the organic metal salts.

The dispersion liquid used for this purpose is generally chosen to be essentially unreactive to the ingredients forming the organic solution as well as the inorganic products being formed. In addition, the dispersion liquid should also have a boiling point above the decomposition temperatures of the organic salts being processed to allow treatment (for example, refluxing) at the desired temperature and avoid excess liquid loss. Depending on the particular dispersion liquid used and nanoparticles formed, it may also be beneficial to include conventional dispersing agents and other adjuvants as further described below to assist in maintaining a stable dispersion and/or achieving desirable rheology properties.

It is noted that the preparation of amorphous nanoparticles according to various embodiments of the invention can be achieved using the same starting materials used by conventional MOD processes, i.e., solutions of organic salts of the metals forming the desired coating. For example, this approach can be conveniently used for producing crystalline coatings from the same starting materials used in the TFA-MOD process, namely metal acetates dissolved in trifluoroacetic acid. In addition, this approach may use the same starting materials used in other conventional MOD process, for example, carboxylate salts such as propionate, formate, malonate, oxalate and, especially, acetate salts optionally dissolved in a suitable solvent.

As discussed above, the dispersing liquid used in this approach may be essentially unreactive to the ingredients forming the organic solution as well as the inorganic products being formed. In addition, the dispersing liquid may have a boiling point above the decomposition temperatures of the ingredients being processed and formed. When metal organic salts are used, such as in the above MOD processes, oxygenated organic liquids can advantageously be used as the dispersing liquids. For example, alcohols, glycols, triols, β-dikenonates, acetylacetonate, and other polyols can be used as can alkoxides, esters, ethers and so forth. For example, ethylene glycol, 1,4-butane diol, decanol and propylene glycol may be used as the dispersing liquid. Other suitable dispersion liquids can be determined by routine experimentation.

In some examples, the nanoparticles may be obtained by dissolving soluble salts of the metals M, Ba, and Cu, and optionally Ca and Sr, in molar proportions that will yield the metal-to-metal ratios desired in a nanoparticle form, for example, and exposing the solution to a temperature sufficient to cause decomposition of the salts and formation of the desired nanoparticles in amorphous form. The salts may be carboxylate salts including, but not limited to acetate, trifluoroacetate, propionate, pivalate, formate, malonate, and oxalate salts. For example, the salts may be acetate salts. The salts may be dissolved in any suitable organic solvent, including, but not limited to, trifluoroacetic acid, acetic acid, ethylene glycol, and butane-1,4-diol. For example, trifluoroacetic acid may be used.

In some examples, the heating of the salt solution may be carried out by adding the solution to a high-boiling solvent at an elevated temperature, for example refluxing 1,4 butanediol (b.p.>200° C.), which results in a colloidal dispersion of amorphous nanoparticles. The resulting nanoparticles may be concentrated, or entirely separated from the suspending solvent, by filtration or centrifugation. Or, the dispersion formed in this way can be directly used for coating substrates by the inventive process.

In addition to the nanoparticles and dispersion liquid formed in any suitable manner, the amorphous nanoparticle dispersion can also contain other adjuvants for improving stability and rheology in accordance with well known technology. Examples include, but are not limited to, dispersing agents, chelating agents, surfactants, thixotropic agents, and so forth. Particular examples of suitable dispersing agents include, but are not limited to, octylamine, octanoic acid, sodium dodecyl benzene sulfonate and polyvinylpyrrolidone.

It will be understood that the concentration of the amorphous nanoparticles in the dispersion can vary widely and essentially any amount can be used. In general, the concentration of nanoparticles should be enough to make the inventive process economically feasible and not be so much that the dispersion becomes unstable or too viscous to be easily used for coating. For example, the nanoparticle colloid/dispersion can contain about 0.1 to 50 wt. % nanoparticles based on the dispersion as a whole. In other examples, the colloid/dispersion may contain about 0.3% to 40 wt %, about 0.5 wt % to 20 wt %, or even about 1 to 15 wt %, amorphous nanoparticles. In some examples, the amount of nanoparticles used is chosen such that the dispersion does not become cloudy (leading to agglomeration), since clear dispersions have better stability. In general, the particular nanoparticle concentration to use in particular embodiments of this invention depends on the particular materials being used and can easily be determined by routine experimentation.

Substrates

This invention can be used to form crystalline coatings on any suitable substrate. In some examples, the methods of this invention may be used to form epitaxial coatings on substrates already exhibiting a characteristic crystallographic structure. In other examples, non-epitaxial coatings may be formed on suitable substrates.

Suitable substrates for epitaxial growth are in many cases known in the art, and may include, for example, metal oxides such as MgO, LaAlO₃, SrTiO₃ and the like, and other materials such as metals, for example, Ni, Ag, Hastalloy, etc., that have the desired crystallographic symmetry for epitaxial growth. The substrate may present a uniform single-crystal face, or it may be textured to expose other crystallographic surfaces. The substrate may optionally be coated with a “buffer” layer such as SrTiO₃ in order to obtain better domain matching for epitaxy. In some embodiments, a metal substrate that is coated with one or more textured buffer layers may be used. Examples of the textured buffer layers may include, for example, but are not limited to, YSZ, MgO, LaMnO₃, SrTiO₃, SrRuO₃, CeO₂, etc.

Low-energy ion beam etching (“IBE”) of a MgO substrate prior to YBCO film deposition has been found effective in minimizing misoriented YBCO grains and promoting the growth of perfectly aligned c-axis YBCO films by vapor deposition processes (J. Du et al. Supercond. Sci. Technol. 18:1035-1041 (2005). In some examples, ion beam etching of the substrate is performed prior to coating with the amorphous nanoparticles.

Depositing the Coating

In embodiments of the methods wherein the amorphous nanoparticles are coated on a substrate, the process of coating may be carried out by any coating method known to one skilled in the art. Examples of suitable methods include, but are not limited to, dip coating, spin coating, flow coating, spray coating, and centrifugal deposition. Any residual dispersion liquid may be removed by evaporation or in any other suitable manner.

The thickness of the coating on the substrate can vary widely, and essentially any thickness can be used. Multiple coatings can also be used, in which case it may be desirable to dry one or more individual coatings before the next is applied.

According to some embodiments, the amorphous nanoparticle coatings are thicker and/or denser as compared to other pre-crystallized coatings prepared using conventional technology. In other words, the concentration of metals per unit volume of coating formed prior to crystallization is greater in embodiments of the present invention as compared to the prior art (e.g., TFA-MOD). This may be due not only to the fact that nanoparticle dispersions can be made with less liquid than corresponding solutions, but also that organic decomposition products, which must pass through the coatings as they are liberated, may be avoided. As a result, thicker crystalline coatings may be formed. The formation of thicker and denser films may also be attributable to greater physical packing of amorphous nanoparticles when applied to substrate surfaces as compared to conventional coating solutions that lack dispersed particles or nanoparticles.

Forming the Crystalline Films

Various methods of forming crystalline films in accordance with embodiments of the present invention will now be discussed. After the amorphous nanoparticle dispersion is applied, it may be dried, i.e., the dispersion liquid may be evaporated. This can be done be any suitable means. For example, the drying may be performed by heating. This heating step can be done by any suitable means such as by conduction, convection or radiant heat. In some examples, exotic and/or expensive heating approaches (e.g. laser heating) may be avoided. In addition, this heating can be done separately or may be part of the heating process used to form the crystalline film, as further discussed below. When multiple coating layers are applied, some or all of these layers can be individually dried, before the next coating layer is applied, as discussed above.

After dispersion liquid evaporation, the coating of amorphous nanoparticles is caused to crystallize on the surface of the substrate, by raising the layer to the crystallization temperature. In some instances, the amorphous nanoparticles are caused to crystallize epitaxially on the surface of the substrate. The “crystallization temperature” is a temperature or range of temperatures below the melting point of the nanoparticle material, at which a phase change from an amorphous to a crystalline state takes place. In other words, the “crystallization temperature” is the temperature at which the components forming the coating nucleate and grow the crystalline film to be formed. The heat treatment may be carried out in any suitable manner. For example, the heat treatment may be carried out by placing the coated substrate in a temperature-controlled oven, or the nanoparticle layer may be directly heated by infrared or laser irradiation.

In some examples, the heat treatment is carried out in an atmosphere containing a gas humidified with water. The gas may include oxygen. Additional inert gases, such as helium or argon, may be present to dilute the oxygen. The coating may be held at the crystallization temperature for a period of time sufficient for formation of the crystalline layer or crystalline epitaxial layer. In another embodiment, the heat treatment is carried out in an atmosphere containing a dry gas of low humidity.

In various embodiments, the present invention departs from the prior art at least in part because the source compounds for supplying the metals of the coating are inorganic compounds that exhibit essentially no organized crystalline structure and that are arranged in the form of nanoparticles. It will be noted that in some embodiments the processes of the instant invention avoid pyrolysis of organic source compounds that normally occurs in prior art processes such as MOD and TFA-MOD. At least one benefit of the instant methods is that the deleterious effects of this pyrolysis, including adverse effects on density and integrity of the formed film caused by the pyrolysis decomposition products, are also avoided. In addition, as noted previously, thicker coatings be achieved according to the instant invention, which in turn may advantageously influence the rate of film heating and end product processing. Additionally, according to various embodiments, the processes avoid generation of noxious HF, which is associated with the TFA-MOD process. However, the conditions needed to form the crystalline coatings according to the various embodiments herein, for example, in terms of the time, temperature and atmosphere necessary to cause nucleation and crystal growth, may be essentially the same or better as compared to the prior art. Accordingly, persons of ordinary skill in the art can select the particular conditions of time, temperature and atmosphere needed to form particular crystalline films by routine experimentation, taking into account prior related technology in this area.

As well-appreciated in the art, the crystalline films produced are useful in a wide variety of different applications including semi-conductor, superconductor, etc., just to name a few.

### EXAMPLES

The following examples are intended for illustration purposes only, and should not be construed as limiting the scope of the invention in any way.

### Example 1

Colloidal Dispersion of YBCO Nanoparticles

A solution of precursor salts (molar ratio of Y:Ba:Cu=1:2:3) was prepared by dissolving 5.14 g of yttrium acetate, 7.76 g of barium acetate and 9.1 g of copper acetate in 20 ml of trifluroacetic acid with gentle heating. This solution was slowly injected into refluxing 1,4-butanediol (50 ml), producing a blue-colored colloid. After 30 minutes, the mixture was cooled and the colloid was filtered through a 0.2 micron membrane, and the filtrate was used directly for coating experiments.

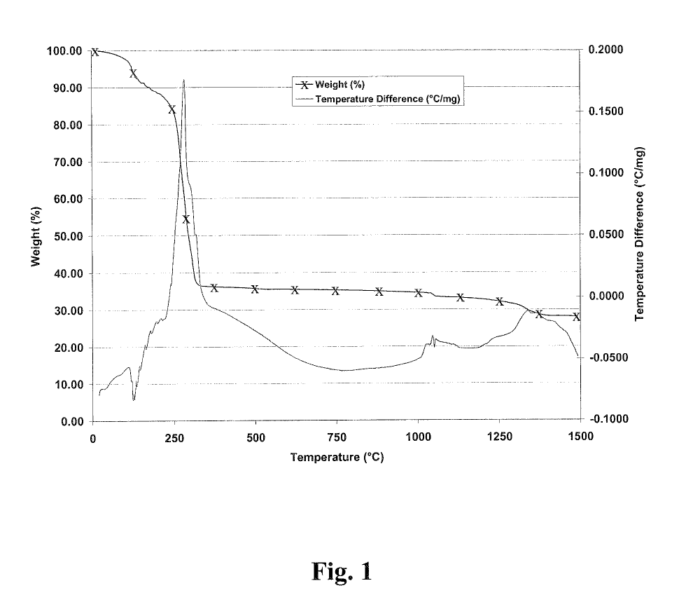

The results of differential thermal analysis and thermogravimetric analysis of a sample of colloid dried at 100° C. are shown in FIG. 1. The majority of weight loss, between about 230° C. and about 320° C., is associated with a strong exotherm and is likely due to the release of solvent (1,4 butanediol). An endotherm between about 1050° C. and about 1060° C. corresponds to the melting point of YBCO.

Crystallization of YBCO Nanoparticle Layer on Substrate

A layer of colloidal YBCO nanoparticles was prepared by spin-coating the filtrate obtained above on the (100) face of a single crystal MgO substrate. Spin-coating was performed at the speed of approximately 3600 rpm for about 2.5 min. The coated layer was dried at about 65° C. for about 5 min. The coating process was repeated to accomplish multi-layered coating. The thickness of the resulting multi-layered coating was approximately 0.2 micron.

The film was heat-treated in an electric furnace according to the following schedule.
1. To 400° C. at 25° C./min (dry Ar/200 ppm O₂)
2. To 775° C. at 25° C./min (wet Ar/200 ppm O₂)
3. To 800° C. at 3° C./min (wet Ar/200 ppm O₂)
4. Dwell at 800° C. for 60 min (wet Ar/200 ppm O₂)
5. To 525° C. at rate of 3° C./min (dry Ar/200 ppm O₂)
6. To 450° C. at rate of 3° C./min (dry 200 ppm O₂)
7. Dwell at 450° C. for 90 min (dry 200 ppm O₂)
8. furnace cooling down to room temperature.

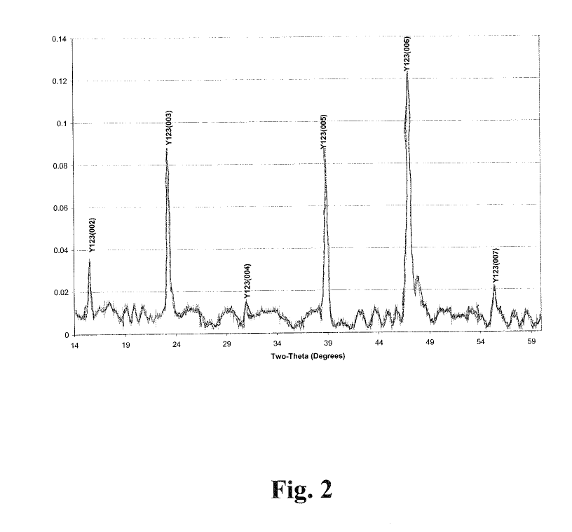

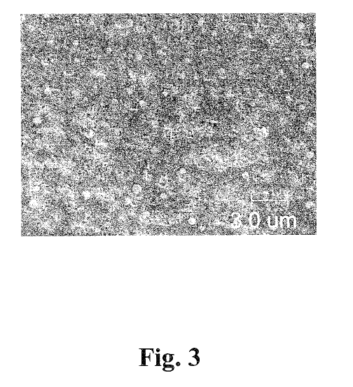

The Ar/200 ppm O₂ atmosphere was maintained at atmospheric pressure. “Wet” atmospheres were essentially saturated with water vapor. The X-ray diffraction pattern (FIG. 2) and the microscopically observed surface (FIG. 3) of a YBCO film produced in this manner indicated that the film was dense and almost completely c-axis oriented in epitaxy with the MgO substrate. Optimization of the heat treatment conditions may minimize or eliminate those few a-axis oriented grains that were observed.

### Example 2

Preparation Cerium Oxide Epitaxial Coating

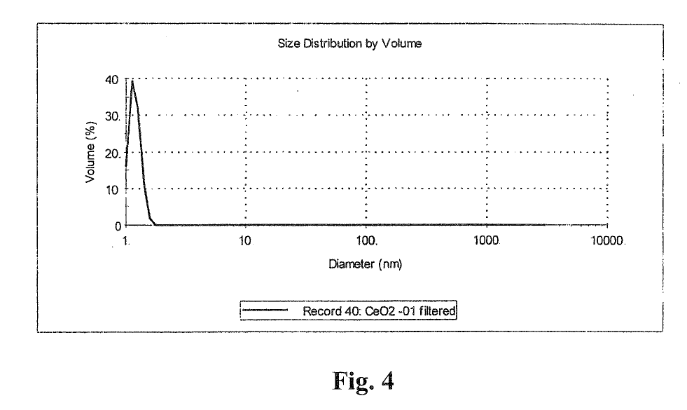

Cerium oxide nanoparticles were prepared by sonication method. Cerium nitrate were used as the precursor material for making cerium oxide nanoparticles and tetra methyl ammonium hydroxide (TMAOH) was used to adjust the pH. In a typical 10 g batch experiment, 26.28 g of cerium nitrate was dissolved in 40 g of water and sonicated for 15 minutes. During the sonication 10 ml of TMAOH was slowly added to achieve the desired pH. A clear colloid was obtained and filtered through 200 nm filter to remove any impurities. Sonication was conducted using solid probe horn with replaceable tip cable of producing oscillations with frequency 20 kHz. The sonicating system was capable of generating 500 watts of power. The particle size distribution of the colloid is shown in FIG. 4.

Epitaxial thin films may be formed by depositing the above clear colloid on single crystalline MgO substrate with (100) orientation using spin coating techniques. Typical speeds can be 3500 rpm with deposition time of 2-3 minutes. Single layer thickness may be about 50 mm. Thicker films can be produced by repeated coatings. The resulting coating can be dried and heat treated at 600° C. to form epitaxial films.

### Example 3

Preparation LaMnO₃ Epitaxial Coating

Lanthanum and manganese acetates were dissolved in trifluoroacetate to make an organometallic complex solution. This precursor solution was injected into hot solvent, 1,4-Butanediol, and the organometallic complex decomposed and formed lanthanum manganese oxide precursor nanoparticles. Due to the non-equilibrium condition and fast kinetics of the reaction extremely fine nanoparticles were formed using this process. Here 1,4-Butanediol has dual nature, as a solvent and also as a surfactant which keeps the formed nanoparticles well separated and unagglomerated. Presence of water was avoided during synthesis in order to eliminate premature hydrolysis of the organo-metallic precursors.

In a typical experiment, 7.09 g of lanthanum acetate and 10.13 g of manganese acetate was dissolved in 20 ml of trifluoroacetic acid and used as a precursor solution. 40 g of 1,4-Butanediol was poured into a round bottom flask and refluxed at 230° C. for 2 hours. Then the precursor mixture was slowly injected into this hot 1,4-Butanediol solution.

Thin epitaxial film coatings may be made on single crystalline MgO substrates with (100) orientation by depositing the above clear colloid on the substrate using spin coating techniques. Typical speeds are 3500 rpm with deposition time of 2-3 minutes. Single layer thickness can be about 100 nm. Thicker films can be produced by repeated coatings. The resulting coating can be dried and heat treated at 700-800° C. to form epitaxial films.

### Example 4

Preparation BaTiO₃ Epitaxial Coating (Hypothetical)

Barium titanate nanoparticles are prepared by the organometallic decomposition method. Barium metal and titanium isopropoxide are used as starting materials for barium and titanium respectively. Making a single bimetallic alkoxide precursor ensures the correct stoichiometry of the product. This reaction mixture is then injected into hot solvent where decomposition takes place and barium titanium oxide particles are formed.

In a typical 10 g batch experiment, 5.89 g of barium metal is added to the flask containing 100 ml of Benzene and 20 ml of isopropanol. Then 12.19 g of titanium isopropoxide is added to the mixture and stirred vigorously until the barium metal is dissolved completely. This reaction mixture is cooled to 4° C. and white precipitate is obtained. This precipitate is separated and mixed with 20 ml of ethanol to make a precursor solution. In a separate flask 40 g of 1,4 Butanediol is refluxed for 2 hours. The precursor solution is injected slowly into hot 1,4 Butanediol solution, where the organometallic complex decomposes to form barium titanate amorphous nanoparticles. Care is taken by distilling the 1,4 Butanediol solution to avoid any presence of water to prevent hydrolysis reaction.

Thin epitaxial film coatings can be made on single crystalline MgO substrates with (100) orientation by depositing the above clear colloid on the substrate using spin coating technique. Typical speeds are 3500 rpm with deposition time of 2-3 minutes. Single layer thickness is about 100 nm. Thicker films are produced by repeated coatings. The resulting coatings are dried and heat treated at 900° C. to form epitaxial films.

It will be obvious to those skilled in the art that various changes may be made without departing from the scope of the invention, which is not to be considered limited to what is described in the specification.

What is claimed is:

1. A process for making a crystalline film on a substrate comprising applying to the substrate amorphous nanoparticles and heating to cause the constituents of the amorphous nanoparticles to nucleate and grow on the substrate to form a crystalline film.

2. The process of claim 1, wherein the amorphous nanoparticles are applied to the substrate in a dispersion.

3. The process of claim 2, wherein the surface of the substrate exhibits a crystallographic structure, and wherein the growth of the crystalline film is epitaxial.

4. The process of claim 2, wherein the crystalline film comprises one or more metal oxides.

5. The process of claim 4, wherein the crystalline film comprises a perovskite.

6. The process of claim 5, wherein the crystalline film comprises a complex perovskite of the formula MₐQ_{b}Cu_{c}Oₓ, wherein
M is one or more metals selected from Y, La, Ce, Pr, Nd, Pm, Sm, Eu, Gd, Tb, Dy, Ho, Fr, Tm, Yb, Lu and Bi,
Q is one or more Group IIa elements selected from Ca, Sr, Mg and Ba, and wherein
c=1-3,
a+b≧c,
a+b+c=3-8, and
x is a number to sufficient to satisfy the valence requirements of the other elements present.

7. The process of claim 6, wherein Q is Ba, Sr or both and in which b+c=2-3.

8. The process of claim 5, wherein the crystalline film comprises a complex perovskite of the formula YBa₂Cu₃O_{7-δ}, and wherein Y may be wholly or partially substituted with one or more of La, Ce, Pr, Nd, Pm, Sm, Eu, Gd, Tb, Dy, Ho, Fr, Tm, Yb, Lu and Bi.

9. The process of claim 1, wherein the amorphous nanoparticles are formed by heating a mixture comprising a liquid and one or more organometallic compounds to decompose the one or more organometallic compounds, and wherein the crystalline film is a metal film.

10. The process of claim 9, wherein the amorphous nanoparticles are applied to the substrate in the form of a dispersion comprising the amorphous nanoparticles and a dispersion liquid, and wherein the amorphous nanoparticles are formed by heating one or more organometallic compounds and the dispersion liquid to decompose the one or more organometallic compounds.

11. The process of claim 1 wherein the crystalline film is a metal oxide crystalline film having predetermined molar ratios of one or more metal oxides and having an average composition selected from the group consisting of M₂Ba₂CuOₓ, MBa₂Cu₃Oₓ, MBa₂Ca₂Cu₃Oₓ, and Bi₂Sr₂CaCu₂Oₓ, and wherein the amorphous nanoparticles are produced by the steps of
(a) dissolving salts of M, Ba, Ca, Bi, Sr, and Cu in an organic solvent, in predetermined molar ratios proportional to the predetermined molar ratios of the metals in the metal oxide crystalline film; and
(b) heating the dissolved salts in the presence of an alcoholic solvent to a temperature at which amorphous nanoparticles are formed;
wherein M represents one or more metals selected from the group consisting of Hg, Tl, and the lanthanide elements, and x has a value between 4 and 9.

12. The process of claim 11, wherein the heating of the dissolved salts is accomplished by adding the solution of salts to a diol at a temperature in excess of 200° C.

13. The process of claim 11, wherein the crystalline film has an average composition selected from the group consisting of M₂BaCuOₓ, and MBa₂Cu₃Oₓ.

14. The process of claim 13, wherein the crystalline film has the average composition of YBa₂Cu₃Oₓ.

15. The process of claim 1, wherein the amorphous nanoparticles have the same stoichiometry as the crystalline film to be formed.

16. A process for forming a stable dispersion of amorphous nanoparticles comprising heating a mixture of a non-reactive solvent and organic salts of one or more metals to a temperature sufficient to cause the one or more organic metal salts to decompose into amorphous nanoparticles that are stably dispersed in the non-reactive solvent.

17. The process of claim 16, wherein the amorphous nanoparticles are formed from a metal oxide or a mixture of metal oxides.

18. The process of claim 17, wherein the amorphous nanoparticles are formed from a perovskite.

19. The process of claim 18, wherein the amorphous nanoparticles are formed from a complex perovskite of the formula MₐQ_{b}Cu_{c}Oₓ, wherein
M is one or more metals selected from Y, La, Ce, Pr, Nd, Pm, Sm, Eu, Gd, Tb, Dy, Ho, Fr, Tm, Yb, Lu and Bi,
Q is one or more Group IIa elements selected from Ca, Sr, Mg and Ba, and wherein
c=1-3,
a+b≧c,
a+b+c=3-8, and
x is a number to sufficient to satisfy the valence requirements of the other elements present.

20. The process of claim 19, wherein Q is Ba, Sr or both and in which b+c=2-3.

21. The process of claim 18, wherein the amorphous nanoparticles are formed from a complex perovskite of the formula YBa₂Cu₃O_{7-δ}, and further wherein Y may be wholly or partially substituted with one or more of La, Ce, Pr, Nd, Pm, Sm, Eu, Gd, Tb, Dy, Ho, Fr, Tm, Yb, Lu and Bi.

22. The process of claim 16, wherein the amorphous nanoparticles are applied to a substrate to form an epitaxial film, a crystalline non-epitaxial film, or other film, and wherein the amorphous nanoparticles and the film formed therewith have the same stoichiometry.

23. A process for forming a metal oxide epitaxial film on a substrate comprising heating a mixture of a non-reactive solvent and at least one organometallic salt to decompose the at least one organometallic salt into amorphous nanoparticles that are stably dispersed in the non-reactive solvent, applying the dispersion of amorphous nanoparticles to the substrate that exhibits a crystallographic structure, and heating to cause the metal constituents of the amorphous nanoparticles to nucleate and grow on the substrate to form an epitaxial crystalline film.
